(19) United States
(12) Patent Application Publication
(10) Pub. No.: US 2025/0203824 A1
(43) Pub. Date: Jun. 19, 2025

(54) PHASE CHANGE COOLING SYSTEM

(71) Applicant: Digital Porpoise, LLC, Austin, TX (US)

(72) Inventors: Jason Wilfred Clark, Milford, NH (US); Steven William Dumas, Great Falls, VA (US)

(21) Appl. No.: 18/981,199

(22) Filed: Dec. 13, 2024

Related U.S. Application Data
(60) Provisional application No. 63/610,291, filed on Dec. 14, 2023.

(51) Int. Cl. H05K 7/20

(52) U.S. Cl. CPC H05K 7/20809; H05K 7/20727; H05K 7/20836

(57) ABSTRACT

Disclosed herein are embodiments of a cooling system for cooling a heat emitting object that can include a conduit having at least a portion thereof in thermal communication with a heat emitting object, a heat exchanger in communication with the conduit, a phase change material, a driving element adapted to advance the phase change material through the heat exchanger and the conduit, and a secondary cooling element to cool the phase change material as it passes through the heat exchanger. The cooling system can be adapted to remove heat from the heat emitting object as the phase change material advances through at least the portion of the conduit that is in thermal communication with the heat emitting object so that at least a portion of the phase change material changes from a solid or a semi-solid phase to a liquid phase from the heat removed from the heat emitting object.

### CROSS-REFERENCE TO RELATED APPLICATIONS AND INCORPORATION BY REFERENCE

This application claims the priority benefit of U.S. patent application No. 63/610,291, filed Dec. 14, 2023 (titled TWO PHASE SOLID TO LIQUID COOLING SYSTEM), the contents of which is incorporated by reference herein in its entirety.

### BACKGROUND

### Field of Disclosure

Aspects of the present disclosure relate generally to the cooling of a surface, a material, or a component and, in some embodiments, a cooling system configured to remove heat from and/or regulate the temperature of a chipset in a data center.

### Description of the Related Art

Heat can generally be transferred to a cooling medium by either sensible heat or by latent heat. Sensible heat is the thermal energy that is received by a cooling medium that increases the temperature of the medium. Latent heat is the thermal energy that is received by a cooling medium that transitions the medium from one state of matter to another. Conventional chipset cooling systems generally remove thermal energy from a system only by sensible heat.

Cooling chipsets in servers is achieved with air for most servers. Due to the increase in density of transistors for chipsets, the requirements for thermal transport from the chipset has also increased. Air has a finite amount of heat energy that it can absorb, store and transport, and the power density of more modern chipsets is reaching the limit of air-based thermal cooling.

Single phase liquid cooling typically uses a block of copper or aluminum, referred to as a heat sink, mounted to the chip and water (or other liquid) flowing through this block to carry heat away from the chips. Single phase liquid cooling has a limited capacity to remove heat which can negatively impact cooling performance, and usually utilize conductive fluid, which can be detrimental to electrical equipment.

Two-phase direct to chip cooling utilizes liquid refrigerant which is boiled or evaporated to allow vapor to carry heat away from chipsets. This requires the use of refrigerants, which can be dangerous to the environment or the working area if leaked from the closed-loop system. Another drawback to two-phase liquid to gas cooling solutions is that, at high temperatures, the refrigerant boils and bubbles, impeding heat transfer. This reduces the effectiveness of a given area of heat sink. Cooling fluids require chemical treatment for bacteria, require careful filtering to avoid corrosion, and can cause microchannel clogging in heat exchangers.

Better thermal management solutions are needed.

### SUMMARY OF SOME EXAMPLE EMBODIMENTS

Disclosed herein are embodiments of a cooling system for cooling a heat emitting object In some embodiments, the cooling system can include a conduit having at least a portion thereof in thermal communication with a heat emitting object, a heat exchanger in communication with the conduit, the heat exchanger comprising a housing comprising an internal chamber, a phase change material, a driving element adapted to advance the phase change material through the internal chamber and the conduit during operation of the cooling system, and a secondary cooling element in thermal communication with the heat exchanger, the secondary cooling element adapted to remove heat from the phase change material as the phase change material is advanced through the internal chamber of the heat exchanger. In any embodiments disclosed herein, the cooling system can be adapted to remove heat from the heat emitting object as the phase change material advances through at least the portion of the conduit that is in thermal communication with the heat emitting object so that at least a portion of the phase change material changes from a solid phase or a semi-solid phase to a liquid phase from the heat removed from the heat emitting object. In some embodiments, at least a portion of the phase change material cools and transitions from the liquid phase to the solid phase or the semi-solid phase as the phase change material passes through the internal chamber and heat is removed from the phase change material by the secondary cooling element.

Also disclosed herein are embodiments of a cooling system that can include a conduit having at least a portion thereof in thermal communication with a heat emitting object, a heat exchanger in communication with the conduit, the heat exchanger comprising a housing comprising an internal chamber, a phase change material, an auger within the internal chamber, the auger adapted to move the phase change material through the internal chamber during operation of the cooling system, a secondary cooling subsystem in thermal communication with the heat exchanger, the secondary cooling element adapted to remove heat from the phase change material as the phase change material is advanced through the internal chamber of the heat exchanger, and a pump adapted to move semi-liquid phase change material through the conduit. In any embodiments disclosed herein, the cooling system can be in thermal communication with a heat emitting object to remove heat from the heat emitting object so that at least a portion of the phase change material changes from a solid phase or a semi-solid phase to a liquid phase. In any embodiments disclosed herein, as the phase change material passes through the internal chamber during operation of the cooling system, at least a portion of the phase change material cools and transitions from the liquid phase to the solid phase.

Also disclosed herein are embodiments of a method of cooling a heat emitting object, the method including removing heat from the heat emitting object by moving a phase change material through a portion of a conduit that can be in thermal communication with the heat emitting object so that the phase change material absorbs heat from the heat emitting object, thereby cooling the heat emitting object, wherein, when the phase change material absorbs heat from the heat emitting object, at least a portion of the phase change material changes from a solid state or a semi-solid state to a liquid state, moving the phase change material away from the heat emitting object and through an internal chamber of a heat exchanger, cooling the phase change material in the heat exchanger to transform at least some of the phase change material from a liquid state to a semi-solid state or a solid state, and moving the phase change material away from the heat exchanger back to the portion of the conduit that is in thermal communication with the heat emitting object. In some embodiments, a driving element in the cooling system moves the phase change material through the cooling system.

Any embodiments of the devices, systems, and methods disclosed herein can include, in additional embodiments, one or more or any combination of the following features, components, and/or details, in any combination with any of the other features, components, and/or details of any other embodiments disclosed herein: wherein the system includes a controller adapted to control operation of at least the driving element and a plurality of sensors adapted to provide data to the controller; wherein the phase change material exiting the heat exchanger can include a mixture of a solid and/or a semi-solid material and a liquid material; wherein the system can be arranged such that the phase change material will be at least mostly in a semi-solid state as the phase change material leaves the heat exchanger; wherein the phase change material can include a soft paraffin; wherein the phase change material can include a hydrogenated salt emulsion, a hydrated salt, calcium chloride, or sodium sulfate; wherein the driving element can include an auger within the internal chamber; wherein a rotational speed of the auger is controlled by a controller; wherein the controller reduces the rotational speed of the auger if a temperature sensor in communication with the conduit detects that a temperature of the phase change material exiting the heat exchanger is above a first temperature; wherein the controller reduces the rotational speed of the auger if a temperature sensor in communication with the phase change material in the conduit detects that a temperature of the phase change material exiting the heat exchanger is above a first temperature; wherein the controller increases the rotational speed of the auger if the temperature sensor detects that a temperature of the phase change material exiting the heat exchanger is below the first temperature; wherein rotation of the auger removes solid phase change material or semi-solid phase change material solidified on a surface of the internal chamber, allowing for more liquid phase change material to contact the internal chamber; wherein the secondary cooling element provides a cooling medium to the housing; wherein the cooling medium cools the internal chamber such that at least a portion of the phase change material transitions from the liquid phase to the solid phase or the semi-solid phase; wherein the internal chamber includes a plurality of surface features adapted to increase surface area between the internal chamber and the cooling medium; wherein the driving element can include a pump adapted to move the phase change material through the conduit; wherein the system includes a heating element positioned on the pump and wherein, if a temperature sensor positioned on the conduit or the pump detects that the phase change material is below a solidification temperature, the heating element heats the phase change material to above the solidification temperature; wherein the system is arranged such that the phase change material will be at least mostly in a liquid state as the phase change material leaves the pump; and/or wherein the conduit further can include a bypass conduit, wherein the bypass conduit diverts from the conduit around the pump so as to bypass the pump and a valve controls a flow of the phase change material through the bypass conduit.

Any embodiments of the devices, systems, and methods disclosed herein can include, in additional embodiments, one or more or any combination of the following features, components, and/or details, in any combination with any of the other features, components, and/or details of any other embodiments disclosed herein: wherein the system includes a controller; wherein, if a pressure sensor detects that a pressure within the cooling system exceeds a threshold pressure value (e.g., without limitation, a safe pressure value or range of values), the controller issues commands to the valve to divert a flow of the phase change material to bypass the pump, and wherein, when pressure within the cooling system returns to below the threshold pressure value, the controller actuates the valve to allow the flow of the phase change material to advance to the pump; wherein the driving element can include an auger positioned within the conduit adapted to move solid phase change material or semi-solid phase change material through the conduit; wherein the driving element can include an auger positioned within the internal chamber and a second auger positioned within the conduit, wherein operation of the auger positioned within the internal chamber is operatively connected to operation of the second auger positioned within the conduit; wherein the system includes a heatsink in thermal communication with the heat emitting object and the portion of the conduit in thermal communication with the heat emitting object; wherein the heatsink can include a plurality of fins adapted to facilitate thermal communication between the phase change material and the heat emitting object; wherein the plurality of fins are arranged in rows aligned on the heatsink to define flow paths for the phase change material to flow through the heatsink; wherein each of the plurality of fins can include a sharp leading edge adapted to separate large solid or semi-solid phase change material segments into smaller solid or semi-solid phase change material segments; wherein each of the plurality of fins can include a dull trailing edge adapted to direct phase change material into the sharp leading edge of fins downstream on the heatsink; wherein each of the plurality of fins is teardrop shaped; wherein the plurality of fins are arranged such that, as the phase change material passes over the heatsink, rows of fins alternate with sharp leading edges and dull leading edges; wherein the plurality of fins are trapezoid shaped; wherein the plurality of fins are rectangular shaped; wherein the heatsink can include a plurality of teardrop shaped fins, a plurality of trapezoid shaped fins, and a plurality of rectangular shaped fins; wherein the system includes an expansion chamber in communication with the conduit, the expansion chamber adapted to accommodate expansion and contraction of the phase change material due to changes of phase; wherein the expansion chamber can include a flexible housing; wherein the expansion chamber can include a rigid housing; and/or wherein the expansion chamber further can include a check valve adapted to allow air to escape the expansion chamber but not allow the phase change material from escaping the expansion chamber.

Any embodiments of the devices, systems, and methods disclosed herein can include, in additional embodiments, one or more or any combination of the following features, components, and/or details, in any combination with any of the other features, components, and/or details of any other embodiments disclosed herein: wherein the system includes a controller adapted to control operation of at least the auger and the pump and a plurality of sensors adapted to provide data to the controller; wherein the phase change material exiting the heat exchanger can include a mixture of solid and liquid; wherein the phase change material exiting the heat exchanger can include a semi-solid phase change material; wherein the phase change material can include a soft paraffin; wherein the phase change material can include a hydrogenated salt emulsion, a hydrated salt, calcium chloride, or sodium sulfate; wherein a rotational speed of the auger is controlled by a controller, the controller reduces the rotational speed of the auger if a temperature sensor in communication with the conduit or the phase change material in the conduit detects that a temperature of the phase change material exiting the heat exchanger is above a first temperature, and the controller increases the rotational speed of the auger if the temperature sensor detects that a temperature of the phase change material exiting the heat exchanger is below the first temperature; wherein rotation of the auger removes solid phase change material solidified on a surface of the internal chamber, allowing for more liquid PCM to contact the internal chamber; wherein rotation of the auger removes semi-solid phase change material solidified on a surface of the internal chamber, allowing for more liquid PCM to contact the internal chamber; wherein the cooling system provides a cooling medium to the housing; wherein the cooling medium cools the internal chamber such that at least a portion of the phase change material transitions from the liquid phase to the solid phase or the semi-solid phase; wherein the internal chamber includes a plurality of surface features adapted to increase surface area between the internal chamber and the cooling medium; wherein the system includes a heating element positioned on the pump and wherein, if a temperature sensor in communication with the conduit, the phase change material in the conduit, or the pump detects that the phase change material is below a solidification temperature, the heating element heats the pump to above the solidification temperature; wherein the conduit further can include a bypass conduit, wherein the bypass conduit diverts from the conduit around the pump so as to bypass the pump, and a valve controls a flow of the phase change material through the bypass conduit; wherein, if a pressure sensor detects pressure within the cooling system exceeds a safe pressure range, the controller issues commands to the valve to divert flow of the phase change material to bypass the pump, and wherein, when pressure within the cooling system returns to the safe pressure range, the controller actuates the valve to divert flow of the phase change material to the pump; and/or wherein the system includes an auger positioned within the conduit adapted to move solid phase change material or semi-solid phase change material through the conduit; wherein operation of the auger positioned within the internal chamber is operatively connected to operation of the auger positioned within the conduit.

Any embodiments of the devices, systems, and methods disclosed herein can include, in additional embodiments, one or more or any combination of the following features, components, and/or details, in any combination with any of the other features, components, and/or details of any other embodiments disclosed herein: wherein the system includes a heatsink in thermal communication with the conduit and the heat emitting object and in fluid communication with the conduit; wherein the heatsink can include a plurality of fins adapted to facilitate thermal communication between the phase change material and the heat emitting object; wherein the plurality of fins are arranged in rows aligned on the heatsink to define flow paths for the phase change material to flow through the heatsink; wherein the plurality of fins comprise a sharp leading edge adapted to separate large solid or semi-solid phase change material segments into smaller solid of semi-solid phase change material segments; wherein the plurality of fins comprise a dull trailing edge adapted to direct phase change material into the sharp leading edge of fins downstream on the heatsink; wherein the plurality of fins are teardrop shaped; wherein the plurality of fins are arranged such that, as the phase change material passes over the heatsink, rows of fins alternate with sharp leading edges and dull leading edges; wherein the plurality of fins are trapezoid shaped; wherein the plurality of fins are rectangular shaped; wherein the heatsink can include a plurality of teardrop shaped fins, a plurality of trapezoid shaped fins, and a plurality of rectangular shaped fins; wherein the system includes an expansion chamber arranged on the conduit, the expansion chamber adapted to accommodate expansion and contraction of the phase change material due to changes of phase; wherein the expansion chamber can include a flexible housing; wherein the expansion chamber can include a rigid housing; and/or wherein the expansion chamber further can include a check valve adapted to allow air to escape the expansion chamber but not allow the phase change material from escaping the expansion chamber.

Any embodiments of the devices, systems, and methods disclosed herein can include, in additional embodiments, one or more or any combination of the following features, components, and/or details, in any combination with any of the other features, components, and/or details of any other embodiments disclosed herein: wherein the method includes controlling an operation of at least the driving element with a controller operatively connected to a plurality of sensors adapted to provide data to the controller; wherein the phase change material exiting the heat exchanger can include a mixture of a liquid material and a semi-solid and/or a solid material; wherein the phase change material can include a soft paraffin; wherein the phase change material can include a hydrogenated salt emulsion, a hydrated salt, calcium chloride, or sodium sulfate; wherein the driving element can include an auger within the internal chamber; comprising controlling a rotational speed of the auger, including reducing the rotational speed of the auger if a temperature of the phase change material exiting the heat exchanger is above a first temperature, and increasing the rotational speed of the auger if the temperature of the phase change material exiting the heat exchanger is below the first temperature; wherein the method includes removing solid or semi-solid phase change material solidified on an inside surface of the internal chamber, thereby allowing for other portions of the phase change material to contact the internal chamber; wherein the method includes cooling the phase change material from the semi-liquid state to the semi-solid state using a secondary cooling element that provides a cooling medium that cools the internal chamber such that at least a portion of the phase change material transitions from the semi-liquid state to the semi-solid state; wherein the internal chamber includes a plurality of surface features adapted to increase surface area between the internal chamber and the cooling medium; wherein the driving element can include a pump adapted to move the phase change material through the conduit; wherein the method includes heating the pump to above the solidification temperature by a heating element positioned on the pump if a temperature sensor positioned on the conduit or the pump detects that the phase change material is below a solidification temperature; wherein the method includes selectively diverting the phase change material around the pump with a valve; wherein the method includes diverting the phase change material around the pump if a pressure sensor detects that a pressure within the heat exchanger exceeds a threshold pressure value and, if the pressure within the heat exchanger returns to a level that is below the threshold pressure value, allowing the phase change material to advance to the pump; wherein the driving element can include an auger positioned within the conduit adapted to move solid or semi-solid phase change material through the conduit; and/or wherein the driving element can include an auger positioned within the internal chamber and a second auger positioned within the conduit, wherein an operation of the auger positioned within the internal chamber is operatively synchronized with an operation of the secondary auger positioned within the conduit so that, if the auger positioned within the internal chamber is operated, the auger positioned within the conduit is also simultaneously operated.

Any embodiments of the devices, systems, and methods disclosed herein can include, in additional embodiments, one or more or any combination of the following features, components, and/or details, in any combination with any of the other features, components, and/or details of any other embodiments disclosed herein: wherein cooling the heat emitting object can include advancing the phase change material through a heatsink in thermal communication with the conduit and the heat emitting object, and wherein the heatsink is in fluid communication with the conduit; wherein the heatsink can include a plurality of fins adapted to facilitate thermal communication between the phase change material and the heat emitting object; wherein the plurality of fins are arranged in rows aligned on the heatsink to define flow paths for the phase change material through to flow the heatsink; wherein the plurality of fins comprise a sharp leading edge adapted to separate large solid or semi-solid phase change material segments into smaller solid or semi-solid phase change material segments; wherein the plurality of fins comprise a dull trailing edge adapted to direct phase change material into the sharp leading edge of fins downstream on the heatsink; wherein the plurality of fins are teardrop shaped; wherein the plurality of fins are arranged such that, as the phase change material passes over the heatsink, rows of fins alternate with sharp leading edges and dull leading edges; wherein the plurality of fins are trapezoid shaped; wherein the plurality of fins are rectangular shaped; wherein the heatsink can include a plurality of teardrop shaped fins, a plurality of trapezoid shaped fins, and a plurality of rectangular shaped fins; wherein the method includes an expansion chamber arranged on the conduit, the expansion chamber adapted to accommodate expansion and contraction of the phase change material due to changes of phase; wherein the expansion chamber can include a flexible housing; wherein the expansion chamber can include a rigid housing; and/or wherein the expansion chamber further can include a check valve adapted to allow air to escape the expansion chamber but not allow the phase change material to escape the expansion chamber.

### BRIEF DESCRIPTION OF THE DRAWINGS

These and other features, aspects and advantages of the present application are described with reference to drawings of certain embodiments, which are intended to illustrate, but not to limit, the present disclosure. It is to be understood that the attached drawings are for the purpose of illustrating concepts disclosed in the present application and may not be to scale.

FIG. 1A shows a diagram of one embodiment of a system utilizing a semi-solid Phase Change Material (herein “PCM”) to mediate the temperature of a surface;

FIG. 1B shows a diagram of one embodiment of a system utilizing a semi-solid PCM to mediate the temperature of a surface, the embodiment configured to mediate the temperature of two cooled surfaces;

FIG. 1C shows a diagram of one embodiment of a system utilizing a semi-solid PCM to mediate the temperature of a surface depicting a technical cooling loop to regulate the heat extracted by the system from a cooled surface;

FIG. 2A shows a diagram of one embodiment of a heat exchanger further comprising an auger to move PCM as it is cooled to its semi-solid form;

FIG. 2B shows an example embodiment of a heat exchanger further comprising an auger to move PCM as it is cooled to its semi-solid form;

FIG. 3 shows a diagram of one embodiment of the system further comprising a pump;

FIG. 4 shows a diagram of one embodiment of the system, comprising an auger within the chamber and a pump positioned proximal to the heat exchanger;

FIG. 5 shows a diagram of one embodiment of the system where the PCM transitions to a semi-gaseous state;

FIG. 6 shows an embodiment of a liquefier configured to remove the thermal energy from a cooled surface through the use of PCM;

FIG. 7 shows an embodiment of a liquefier with a plurality of surface features configured to remove the thermal energy from a cooled surface through the use of PCM;

FIG. 8 shows an embodiment of a PCM coolant system to regulate the temperature of a cooled surface, such as a computer chipset; and

FIGS. 9A through 9C show embodiments of heatsinks designed for use with a phase change material.

### DETAILED DESCRIPTION OF SOME EXAMPLE EMBODIMENTS

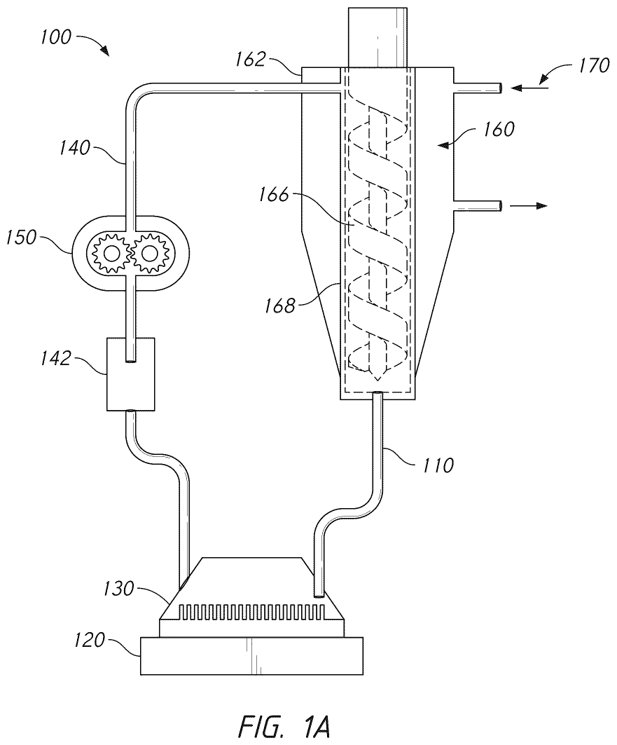

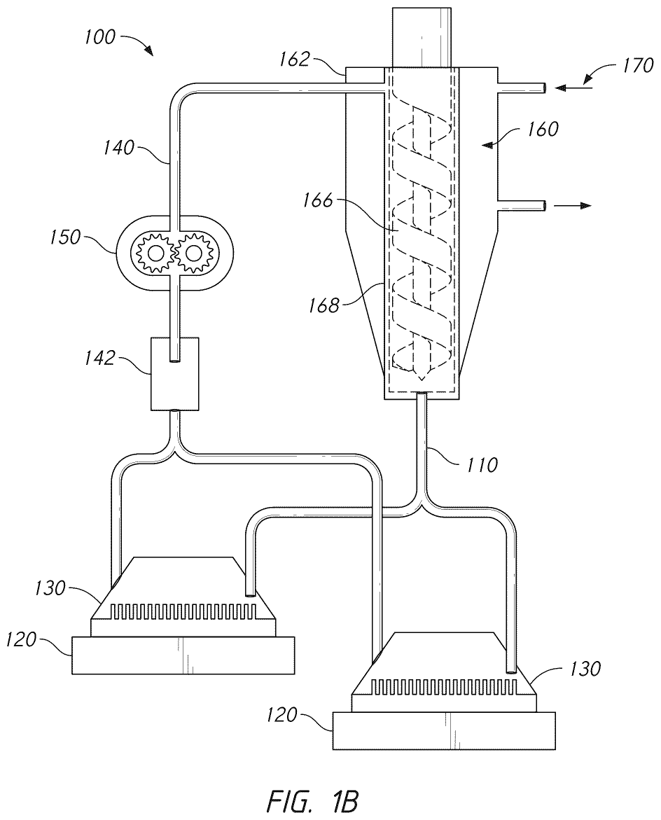

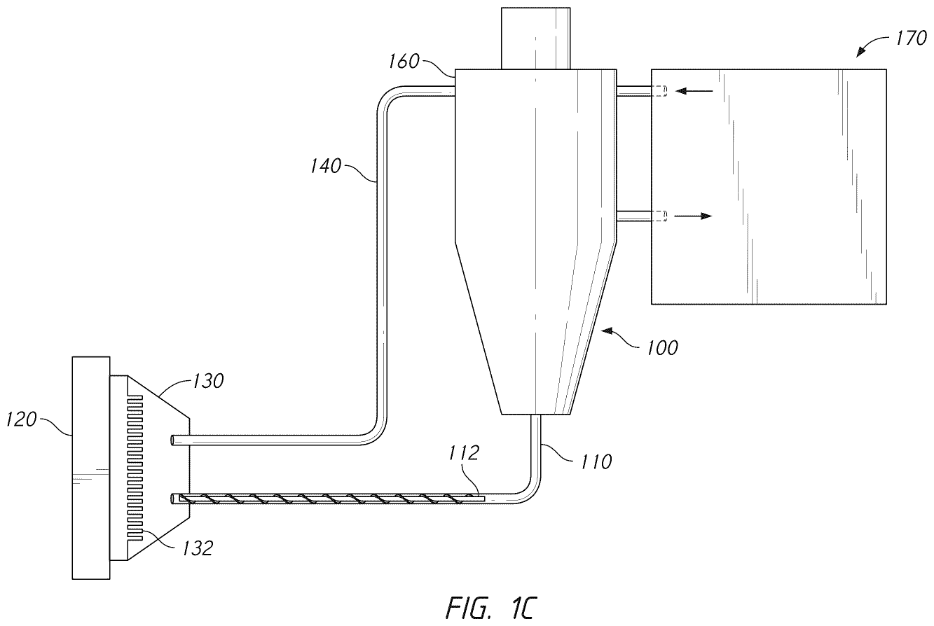

Embodiments disclosed herein relate to systems and methods comprising a solid and/or a semi-solid phase change material (herein “PCM”) to mediate the temperature of a heat emitting object (also referred to herein as a heat producing component, a heat producing object, a heat generating component, a heat producing element, or heat source). In any embodiments disclosed herein, without limitation, the heat emitting object can be an electronic component such as a chipset or any electronic component or any component found in a data room. In any embodiments disclosed herein, the heat emitting object can be any surface, material, or other object that produces heat or for which thermal management or heat reduction is desired. For example and without limitation, heat emitting object can be a chipset or electronic component in a data processing center, shown diagrammatically in FIGS. 1A through 1C. At least some embodiments of the cooling system herein can be referred to as a thermal two-phase cooling system.

An advantage of some embodiments of the cooling system disclosed herein can be that liquid cooling mediums generally have significantly greater capacity per unit of area (e.g., orders of magnitude greater capacity) than that of air. Additionally, liquid cooling can be more effective at transporting heat away from server chipsets than other types of cooling systems as power densities increase. Additionally, in some embodiments, melting a solid or a semi-solid to a liquid can capture more energy per given transfer area than a liquid to gas phase transition or of just heating a liquid without a phase transition. Advantageously, some embodiments of the present disclosure can operate without the use of harmful PFAS chemicals (e.g., forever chemicals).

When absorbing energy via latent heat transfer and undergoing phase change, the temperature of the thermal mediator remains constant while heat is absorbed, unlike a conventional single-phase system where temperature increases as heat is removed. Taking advantage of both latent heat capacity and sensible heat capacity of a thermal mediator can thus require less mediator with a two-phase cooling system as described herein to obtain the equivalent heat transfer of a conventional single-phase cooling system.

In some aspects, embodiments of the cooling system disclosed herein utilize semi-solid PCM and move it from a heat exchanger 160 to a heat source 120 (e.g., a heat emitting object) where it can melt by absorbing thermal energy from the heat source. When in an operable state, the driving elements within the cooling system 100 can flow PCM through the system to cool a heat source 120. A heatsink 130 can assist in increasing the transfer of thermal energy. The heatsink 130 can contain a portion of the PCM while the PCM transmits the thermal energy away from the heat source 120. In some embodiments, the heat source can be a chipset in a data center. As the PCM melts, it absorbs thermal energy in the form of latent heat as it turns from solid to liquid.

Once sufficient thermal energy has been transferred from the heat source 120 to the PCM, the PCM can return to the heat exchanger 160 via an second conduit 140 at a second temperature. In some embodiments, the returning PCM can be a liquid. In some embodiments, the returning PCM can be a liquid with solid suspensions of PCM and/or other additives. In some embodiments, the returning PCM can be a combination of liquid and gaseous PCM. In some embodiments, the PCM within the second conduit 140 can be transported to heat exchanger 160 by a single or two stage pump system, or other methods known by one skilled in the art for fluid transfer.

Once in the heat exchanger 160, the returning PCM can be solidified and/or cooled by a secondary cooling element 170 (also referred to herein as a secondary cooling system or a secondary cooling subsystem), which in some embodiments can include an external source of cooled water provided by a technical cooling loop, or other cooling methods known by one skilled in the art for heat exchangers or the like. Other mediums can be utilized to transport heat from the heat exchanger out of the data center such as refrigerants. In some embodiments, once the returning PCM has been sufficiently cooled to reach a solid or semi-solid state and reach an outgoing temperature, the now solid/semi-solid PCM can be transported back to the chip via the first conduit 110 to continue the cooling cycle.

In some embodiments, the system can be sealed and the PCM can be non-toxic, solid at room temperature, inexpensive, and readily available. Generally, PCM contains no PFAS chemicals and is not conductive. Advantageously, the quantities of PCM required for the average processor cooling system can be much lower in volume compared to standard thermal mediators for cooling systems. Advantageously, a PCM used in the system can be non electrically-conductive such that, in the event of a leak, any electrical components that are contacted by the PCM are not electrically damaged. As disclosed herein, in some embodiments, a semi-solid PCM can refer to an amorphous state that shares qualities with both solid and liquid, being that it can support its own weight while also conforming to a shape of a container. In any embodiments disclosed herein, without limitation, when the PCM is at room temperature, the PCM can include a liquid, a solid, a semi-solid, a soft solid, a mobile solid, and/or a non-Newtonian fluid, or any combination of the foregoing. For example and without limitation, some embodiments of the system can include a PCM including a liquid and a semi-solid material (optionally with other materials or ingredients) when the PCM is at normal room temperature, or can include a PCM including a liquid, a semi-solid material, and a solid material (optionally with other materials or ingredients) when the PCM is at normal room temperature, or can include a PCM including a liquid and a solid material (optionally with other materials or ingredients) when the PCM is at normal room temperature. In some embodiments, the semi-solid material can be petroleum jelly or a similar substance. In any embodiments disclosed herein, the PCM can include petroleum jelly or a similar substance. In any embodiments disclosed herein, the PCM can also or alternatively include any other desired liquid, solid, semi-solid or other matter. In some embodiments disclosed herein, a semi-solid material refers to an amorphous state that shares qualities with both solid and liquid, being that the material can support the material's own weight while having the ability to flow under pressure.

In some embodiments, the heat exchanger 160 can comprise an internal chamber 168 configured to remove thermal energy from the PCM to convert it from a semi-liquid state from the second conduit 140 to a semi-solid state in first conduit 110. In some embodiments, chamber 168 can comprise an integrated pump to further assist in the processing of PCM by the heat exchanger 160.

In some embodiments, the chamber 168 can contain an auger 166, spiralized gear, or another apparatus used by one skilled in the art for transportation of a solid or semi-solid material through a shaft. In some embodiments, the auger 166 can be powered by a drive motor. In some embodiments, the drive motor can provide mechanical power to both the auger 166 and an integrated pump located within the chamber 168. In some embodiments, the auger 166 can aid moving the viscous PCM through the system as it transitions from a liquid to a solid. In some embodiments, the auger 166 can be positioned within the chamber 168 and/or the first conduit 110 to aid the transportation of the semi-solid PCM to the cooled surface. In some embodiments, the cooling system 100 can be configured such that as the auger 166 rotates, the semi-solid PCM is forced out from the internal chamber 168. In some embodiments, the auger 166 can rotate at, approximately at, below, or above 100 rotations per minute, as desired or required. The speed at which the auger rotates can be modified based on the desired outgoing temperature for the semi-solid PCM, the material properties of the PCM, or other factors as desired or required that would be known by one skilled in the art.

In some embodiments, the PCM can be formulated to melt at 98° F. and can be adjusted to meet other transition temperatures as desired or required. In some embodiments, the PCM can be a semi-solid mix of hydrocarbons such as, for example, a soft paraffin or petroleum jelly configured to melt at approximately 99° F. In embodiments utilizing water within the secondary cooling element 170 to cool the PCM in the internal chamber 168, the water can enter the cooling system at a temperature suitable to remove thermal energy from the PCM, such as 68° F. In some embodiments, the liquid PCM can enter the internal chamber 168 in a temperature range between 104 and 120° F. In some embodiments, the semi-solid PCM can exit the internal chamber 168 and be directed by an auger or the like in a temperature range between 7° and 90° F. The flow rate of the medium within the secondary cooling element 170 can be adjusted as desired or required to effectuate sufficient latent or sensible heat transfer from the PCM within the heat exchanger 160. A hydrated salt/paraffin composite (HPC) can be utilized to change the properties of the heat transfer medium. This is hydrated salt emulsified in soft paraffin or petroleum jelly can extend the heat capacity of the heat transfer medium. Petroleum Jelly enthalpy is approx. 96 J/g. Addition of hydronated salt emulsification can add 100 or more J/g to the cooling medium. This additional heat capacity aids in reducing the volume of cooling medium required to move a given amount of heat from the chipsets. The hydrated salt stays in suspension within the soft paraffin or petroleum jelly to reduce the undesirable effect of corrosion to system materials. The ratio can be adjusted to create differing ranges of melt and freeze temperatures. A hydrated salt and paraffin between a 2:1 ratio to 1:1 ratio was utilized. Other chemicals can be used to create a similar effect, including but not limited to Calcium Chloride and Sodium Sulfate.

In some embodiments, the cooling system 100 can further comprise an expansion chamber 142 positioned after the heatsink 130 and before the pump 150. In some embodiments, the PCM within the system is configured to be in a semi-liquid state upon leaving the heatsink 130 and returning to the heat exchanger 160. In some embodiments, the PCM can be configured to expand upon melting within the heatsink 130 when exposed to the heat source 120 during operation. In some embodiments, the expansion chamber 142 can be configured to accommodate the PCM upon its conversion to a liquid state. In some embodiments, the PCM can expand by 3% to 5% by volume when converting from its semi-solid state to liquid state.

In some embodiments, the heatsink 130 can include a plurality of fins configured to be in fluid communication with the PCM as the PCM undergoes phase change and temperature change within the heatsink 130 during operation of the cooling system 100. The fins within the heatsink 130 can assist in the thermal transfer from the heat source 120 to the PCM by increasing the surface area from which the PCM can absorb thermal energy. Furthermore, the fins can assist in separating the semi-solid segments of the PCM into smaller segments in suspension of the liquid PCM, further increasing the speed of latent heat transfer.

In some embodiments, the cooling system 100 can include a plurality of heatsinks 130 and heat sources 120 cooled by the PCM. FIG. 1B depicts an embodiment of a cooling system 100 in which the first conduit 110 diverts to feed into two heatsinks 130, where each heatsink 130 cools a separate heat source 120. In some embodiments, the heat sources 120 can be microprocessors arranged within a computer server, however the heat source 120 can be any heat generating object which could benefit from cooling. The flow within the second conduit 140 can divided between two or more heatsinks 130 such that a singular heat exchanger 160 can provide cooled semi-solid PCM at an outgoing temperature to multiple heat sources.

In some embodiments, the distribution of the flow within the first conduit 110 to the multiple heatsinks 130 can be self-regulating. This can occur as a heatsink 130 subjected to a lower thermal load would not transmit as much thermal energy to the PCM within the liquefier. The PCM in that instance could have a lower viscosity, and the first conduit 110 leading to that liquefier would have a higher pressure drop, therefore limiting the flow to that liquefier. A hotter heatsink 130 would transmit more thermal energy to the PCM, which would liquefy the semi-solid PCM more quickly. In such hotter liquefiers, the PCM would flow more freely when in its more-liquid state, thus decreasing the pressure drop and increasing the flow to that liquefier. In some embodiments, the distribution of the flow within the first conduit 110 can be regulated through the use of a flow distribution valve, which can be controlled by a sensor control system as disclosed herein.

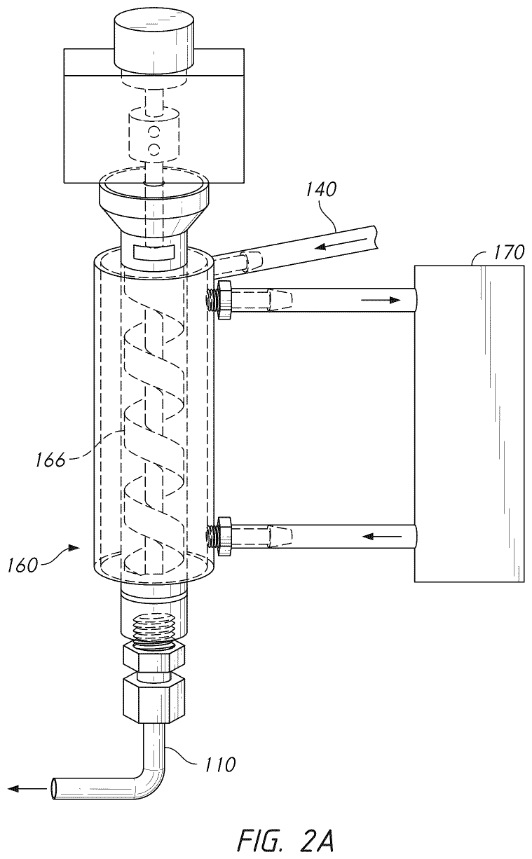

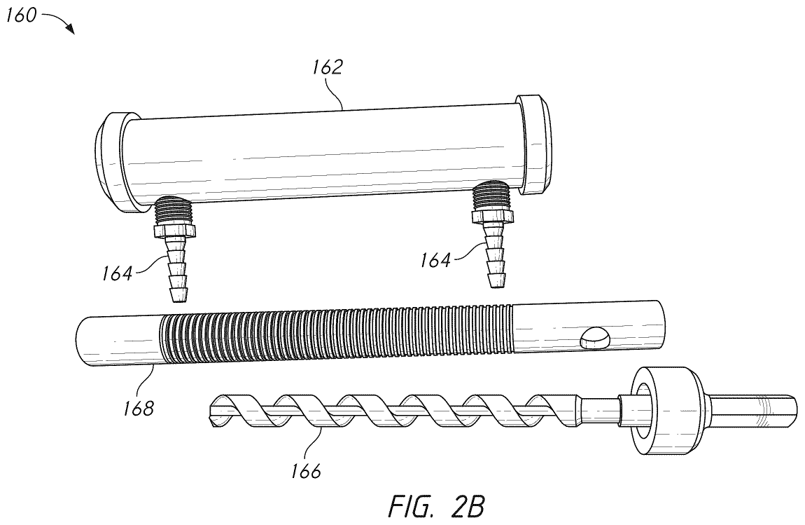

FIGS. 2A and 2B show an example embodiment of a heat exchanger 160 further comprising an auger 166 to move PCM as it is cooled to its semi-solid form. The heat exchanger 160 of this embodiment can utilize a secondary cooling element 170 which is configured to cool an internal chamber 168 which houses the auger 166. The internal chamber 168 can act as a thermal transfer wall for the cooling system 100 to transmit energy between the PCM and the medium within the secondary cooling element 170. The internal chamber 168 can on one end receive semi-liquid PCM and, after being cooled by the fluid provided by the secondary cooling element 170, on the other end eject semi-solid PCM to the first conduit 110. The internal chamber 168 can further comprise features which assist in the thermal transfer between the internal chamber 168 and the PCM within the internal chamber 168, such as ridges to increase the effective surface area of the outer surface of the internal chamber 168 in contact with the medium used in the secondary cooling element 170. The auger 166 can rotate within the internal chamber 168 to assist the movement of semi-solid PCM through the internal chamber 168. The internal chamber 168 can be configured such that the inner surface is in communication with the PCM as it passes through the internal chamber 168 and the chamber's outer surface is in communication with the medium used within the secondary cooling element 170 to cool the internal chamber 168.

As disclosed herein, the pump 150 can be one of several pump types as known by one skilled in the art. As such, the pump 150 can be an external gear pump, an internal gear pump, a lobe pump, or any other suitable pump as would be known and used by one skilled in the art.

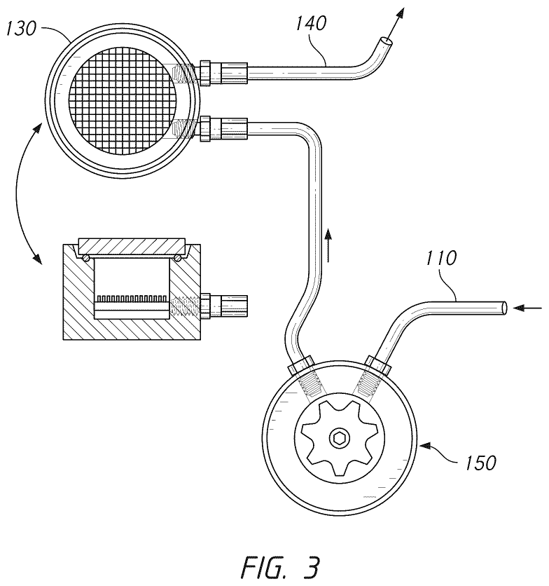

FIG. 3 shows an example embodiment of the cooling system 100 further comprising a pump 150. In some embodiments, the pump 150 can assist in transportation of the PCM through the system. In some embodiments, the pump 150 can be positioned along the first conduit 110 moving semi-solid PCM from the heat exchanger 160 to the heatsink 130. In some embodiments, the pump 150 can be positioned along the second conduit 140 to move the returning PCM from the heat source 120 to the heat exchanger 160.

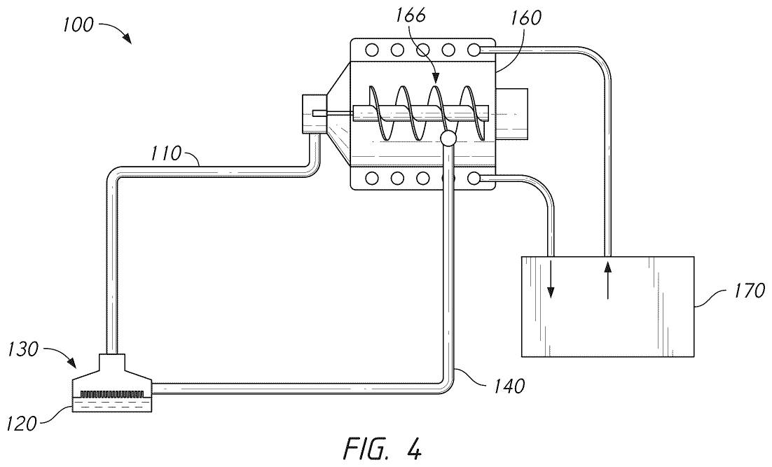

FIG. 4 shows an alternative embodiment of the first conduit 110, where the heat exchanger 160 further comprises an internal chamber 168 within the chamber.

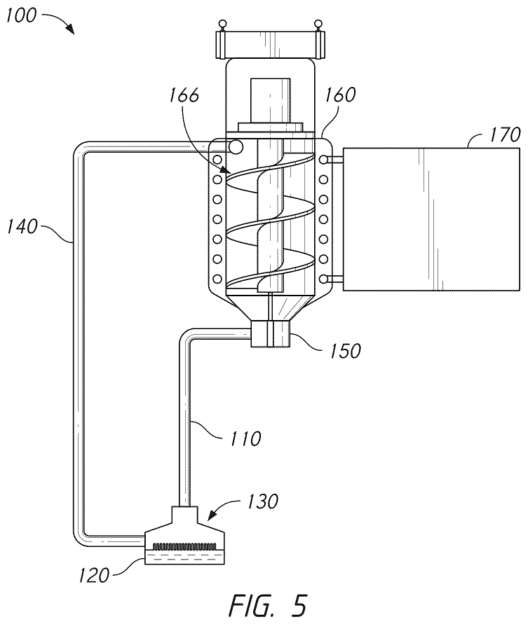

FIG. 5 shows an alternative embodiment of the cooling system 100 where the PCM within the heatsink 130 against the heat source 120 transitions from a semi-solid PCM to a fluid that is a combination of a liquid and a gas. Semi-solid can also refer to a soft solid or mobile solid or non-Newtonian fluid. In such embodiments, more thermal energy can be transmitted from the heat source 120 per unit mass provided by heat exchanger 160, which can advantageously allow for slower operating speeds of any auger 166 or pump 150 within the system.

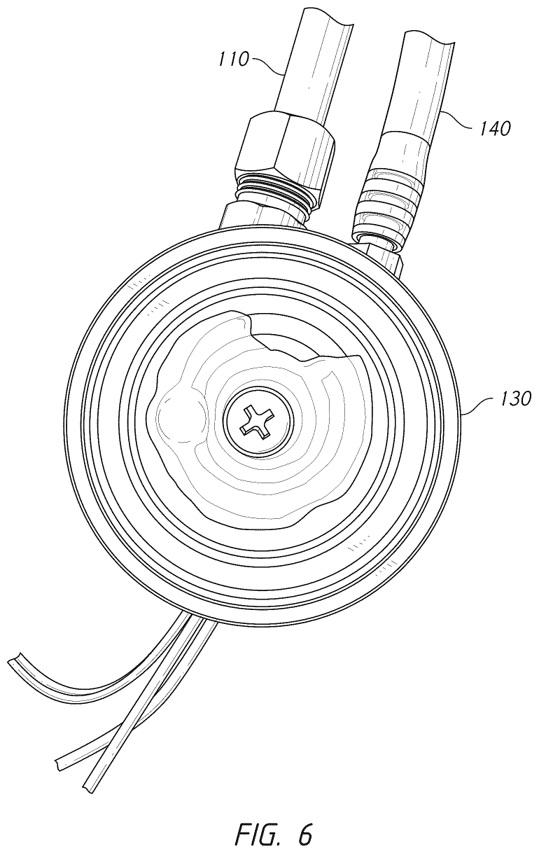

FIG. 6 shows an embodiment of a heatsink 130 configured to remove the thermal energy from a heat source 120 through the use of PCM. Semi-solid PCM is provided by the first conduit 110 to provide the heatsink 130 with PCM at a temperature and phase of matter suitable to remove thermal energy from the heat source 120. The semi-solid PCM can be at an outgoing temperature as described herein when entering the heatsink 130. Once the PCM received from the first conduit 110 has received enough thermal energy from the heat source 120, as desired or required, the PCM can leave the heatsink 130 via an second conduit 140 configured to transport the returning PCM to the heat exchanger 160. The semi-solid PCM can be at an ingoing temperature as described herein when leaving the heatsink 130.

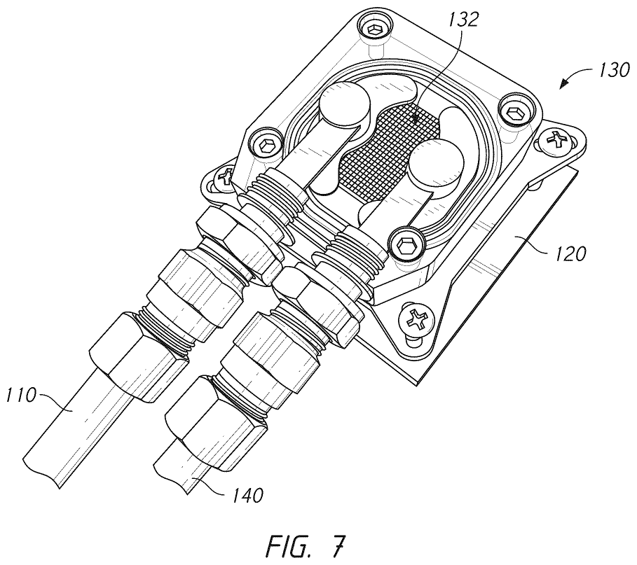

FIG. 7 shows an embodiment of a heatsink 130 configured to remove the thermal energy from a heat source 120 through the use of PCM. Semi-solid PCM is provided by the first conduit 110 to provide the heatsink 130 with PCM at a temperature and phase of matter suitable to remove thermal energy from the heat source 120. The semi-solid PCM can be at an outgoing temperature as described herein when entering the heatsink 130. In some embodiments, the heatsink 130 can have a plurality of fins 132 to increase the surface area exposed to the PCM. The fins 132 can define a flow path designed to assist the distribution of thermal energy from the heat source 120 to the PCM. The flow path of the PCM through the fins 132 of the heatsink 130 can be designed such that as the PCM would reach the connection between heatsink 130 and the second conduit 140, a desired amount of thermal transfer would take place from the heat source 120 to the PCM. Once the PCM received from the first conduit 110 has received enough thermal energy from the heat source 120, as desired or required, the PCM can leave the heatsink 130 via an second conduit 140 configured to transport the returning PCM to the heat exchanger 160. The semi-liquid PCM can be at an ingoing temperature as described herein when leaving the heatsink 130.

In some embodiments, the PCM from the first conduit 110 can include material that is in a solid state or in a semi-solid state, e.g., without limitation, where the PCM includes a mixture of solid and liquid materials at room temperature, or a mixture of semi-solid and liquid materials at room temperature, or a mixture of solid, semi-solid, and liquid materials at room temperature. Semi-solid can also refer to a soft solid or mobile solid or non-Newtonian fluid. In some embodiments, the PCM from the first conduit 110 can be in a solid state. In some embodiments, the PCM from the first conduit 110 can be in a liquid state. In some embodiments, the PCM from the second conduit 140 can be in a semi-liquid state, where it is a mixture of liquid and solid, with more content being liquid than solid. In some embodiments, the PCM from the second conduit 140 can be in a liquid state. In some embodiments, the PCM from the second conduit 140 can be in a semi-gaseous state, where some of the PCM is in gaseous form and some of the PCM is in liquid form. In some embodiments, the PCM from the second conduit 140 can be in a gaseous state.

In some embodiments, the cooling system 100 can further include a controller 200 configured to regulate the flow rate of the PCM within the first conduit 110 and second conduit 140. The temperature control system can be connected to sensors within the cooling system 100, connected to components such as the heat source 120 or heatsink 130. The speed of rotation for the auger 166 can be adjusted based on the data gathered and processed by the sensor connected to heat source 120 or heatsink 130. Sensor data can include electrical current of auger motor and pumps where this can be an indication of the solidification process. Higher operating current indicates solidification of the material. Lower electrical current indicates more liquid and less solid or semi-solid PCM.

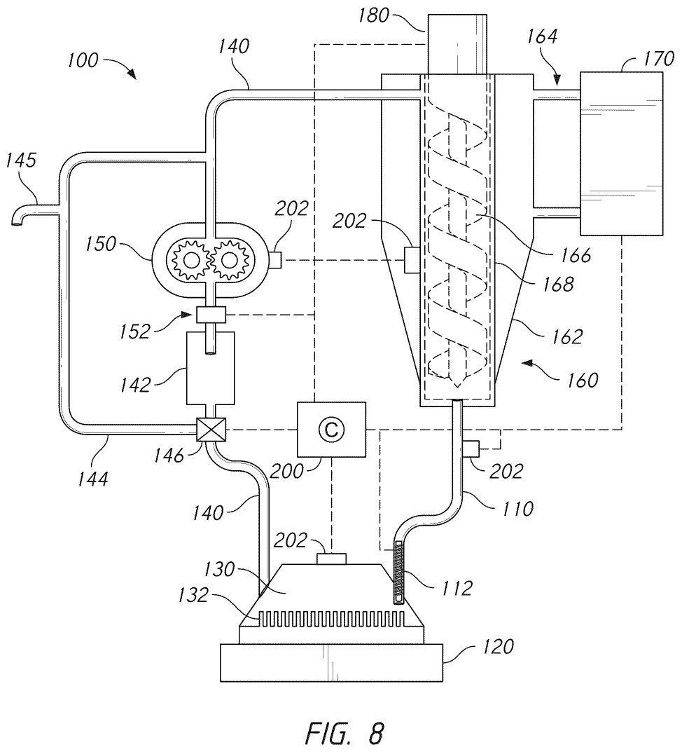

FIG. 8 depicts an embodiment of a cooling system 100 which can be substantially similar to other systems as disclosed herein. When in an operable state, the driving elements within the cooling system 100 can flow PCM through the system to cool a heat source 120. A cooling system 100 can generally include a first conduit 110, a heatsink 130, a second conduit 140, a pump 150, a heat exchanger 160, a secondary cooling element 170, and a controller 200. A cooling system 100 can generally utilize a PCM as a cooling medium to cool a surface 120. The PCM cycled within the cooling system 100 can transition from one state of matter to another during the course of a full cycle. In some embodiments, the PCM can transition, from a combination of solid and liquid or from semi-solid form, to a heated liquid which can include some solid particles, back to the combination of solid and liquid or semi-solid, through the course of a complete cycle through the cooling system 100. A cycle can comprise starting in a heat exchanger 160, moving through a first conduit 110 to a heatsink 130, then to a second conduit 140 drawn by a pump 150 back to the heat exchanger 160.

Advantageously, by modifying certain portions of this cooling system 100 compared with conventional chipset cooling systems, the present disclosure can have a higher coefficient of performance compared to conventional systems. A coefficient of performance can refer to a ratio between the amount of thermal energy moved from a cooled surface compared to the amount of energy consumed by the process of moving that thermal energy. Herein, density can refer to the amount of thermal energy that can be moved from a chipset, with the units of Watts/cm², where the cm² refers to the surface area of the chipset being contacted by the cooling system 100.

In some embodiments, by utilizing one or more of the features and/or aspects disclosed herein, the cooling system 100 could reach a coefficient of performance between 5:1 and 9:1.

A first conduit 110 can transport PCM from the heat exchanger 160 to the heatsink 130. The heatsink 130 can be in thermal communication with the heat source 120 and fluid communication with the first conduit 110 and second conduit 140. PCM in the first conduit 110 can be in a semi-solid state such that part of the PCM is solidified and part of the PCM is a liquid suspending said solids. PCM in the first conduit 110 can be transmitted to the heatsink 130 by various pumping methods, including but not limited to an auger 166, a pump 150, or a secondary auger 112 arranged within the conduit. The cooling system 100 can include one or more driving elements to advance PCM through the cooling system 100. Various embodiments of driving elements can be used in a singular cooling system 100, including but not limited to augers positioned within conduits such as an auger 112 in the first conduit 110, a pump 150, and/or an auger 166 within the heat exchanger 160. Any or all of the components described can contribute to the flow of PCM through the conduits of the cooling system 100. The conduits utilized within the cooling system 100 can utilize full port fittings to reduce restrictions at PCM connections in the cooling system 100. Similarly, the conduits can advantageously have long sweep bends to reduce potential restrictions caused by restrictive bends between components connected by the conduits.

In some embodiments, the semi-solid PCM in the first conduit 110 can exit the heat exchanger 160 at a temperature of approximately 88 degrees Fahrenheit. The ideal temperature of the PCM can vary based on the PCM chosen for the cooling system 100, taking into account its solidification and melting temperatures and general viscosity.

In some embodiments, the first conduit 110 can further include an auger 112 designed to increase the flow rate of the semi-solid PCM through the conduit. In some embodiments, the auger 112 can rotate within the first conduit 110 such that it helps emulsify and/or transport the semi-solid PCM through the first conduit 110 from the heat exchanger 160 to the heatsink 130.

The auger 112 can be of a flexible design so as to not damage or puncture the surrounding conduit. In some embodiments, the outer threads of the auger 112 can occupy the entire cross-section of the conduit so that PCM cannot flow around the outer threads of the auger 112. In some embodiments, the outer threads of the auger 112 can occupy only a portion of the cross-section of the conduit so that PCM can flow around the outer threads of the auger 112.

In some embodiments, the auger 112 can be powered by the motor 180 connected to the auger 166 or be powered by any other way such as a motor system. In some embodiments, rotation of the auger 112 in the conduit can be operatively linked to rotation of the auger 166 of the heat exchanger 160, such that the rotational speed of the auger 166 can be linearly related to rotational speed of the auger 112. In some embodiments, the auger 112 can be controlled by a controller 200 to selectively control its rotational speed and/or its operation.

In some embodiments, once the semi-solid PCM within the first conduit 110 reaches the heatsink 130, PCM can receive thermal energy from a surface 120 to be cooled by the cooling system 100. The heatsink 130 can be in thermal communication with the heat source 120 by way of standardized thermal transfer methods for chipsets, such as thermal paste compound, thermal pads, thermal tapes, thermal epoxies, and/or other systems for thermal transfer, including but not limited to liquid metal or other mediums. The heatsink 130 can be in thermal communication with the PCM by a plurality of fins 132 that can extract thermal energy from the heat source 120. The cooling system 100 can be designed such that, for the thermal energy expected to be provided by the heat source 120, the semi-solid PCM in the heatsink 130 can undergo a partial phase change as the semi-solid PCM liquefies and absorbs energy in the form of latent heat, and the liquid PCM absorbs energy in the form of sensible heat.

In some embodiments, the heatsink 130 can include a plurality of fins 132 configured to facilitate transfer of the PCM from the first conduit 110 to the second conduit 140 while removing thermal energy from the heat source 120. In some embodiments, the fins 132 can increase the surface area where the PCM can contact the heatsink 130, thus increasing the thermal energy transfer rate between the heatsink 130 and the PCM. In some embodiments, the fins 132 can assist in separating the semi-solid segments of the PCM into smaller segments in suspension of the liquid PCM, further increasing the speed of latent heat transfer.

In some embodiments, the heatsink 130 can include one or more temperature probes 202 in communication with a controller 200 to issue commands regarding operation of the cooling system 100. The controller 200 can include a plurality of sensors positioned throughout the cooling system 100 to sense conditions at and/or send instructions to various elements/portions of the cooling system 100. The temperature probes 202 can be positioned at one or more of the positions at and/or around the heatsink 130: at the first conduit 110, within the heatsink 130, in contact with one or more fins 132, along a heatsink base 134, suspended within the heatsink 130 in contact with the PCM, or at the second conduit 140. In some embodiments, the controller 200 can control flow through the cooling system 100 such that the PCM passes through the heatsink 130 at a specific rate. The controller 200 can control the flow such that the PCM exiting the heatsink 130 by the second conduit 140 can vary by no more than 5 degrees Fahrenheit between cycles of the cooling system 100. In some embodiments, the controller 200 can control the flow such that the PCM exiting the heatsink 130 by the second conduit 140 is approximately 126 degrees Fahrenheit. In some embodiments, the controller 200 can control the flow such that the PCM exiting the heatsink 130 does not solidify until reaching the heat exchanger 160.

In some embodiments, PCM heated by the heatsink 130 can be extracted by a second conduit 140. The PCM entering the second conduit 140 would ideally be entirely liquid. Due to the phase change of the PCM between the first conduit 110 and the second conduit 140, pumping the liquid PCM back to the heat exchanger 160 may require alternative methods compared to pumping the semi-solid PCM to the heatsink 130.

In some embodiments, the second conduit 140 can include an expansion chamber 142 to accommodate any change in volume as a result of the phase changes of the PCM as it passes through the cooling system 100. In some embodiments, the first conduit 110 can include an expansion chamber 142. The expansion chamber 142 can have a housing which is rigid or flexible. In some embodiments, if the expansion chamber 142 has a flexible housing, expansion and contraction of the expansion chamber 142 can assist in limiting the amount of air moving through the cooling system 100.

The expansion chamber 142 can include check valves that allow air to escape the system but do not allow PCM to exit the system. Removing air from the cooling system 100 through the use of an expansion chamber 142, a check valve, or by other systems can increase the coefficient of performance for the cooling system 100. In some embodiments, the expansion chamber 142 can have a portion of the conduit removing the phase change material extend within the expansion chamber 142 such that any air present in the loop moves to a top portion of the expansion chamber 142 and thus can be separated from the PCM leaving the expansion chamber 142. In some embodiments, the expansion chamber 142 can trap gasses infused in the PCM for later venting. In some embodiments, the conduit extending partially into the expansion chamber 142 can assist in providing a continuous column of semi-liquid or liquid PCM for a pump 150 to operate efficiently.

In some embodiments, the expansion chamber 142 can be fitted with filters designed to prevent circulation of large impurities through the cooling system 100. As the PCM is expected to be in a liquid state at an expansion chamber 142 arranged on a second conduit 140, the solid particles at that point could be impurities and/or debris circulating within the cooling system 100.

The expansion chamber 142 can be designed to be easily removable from the cooling system 100 without substantially leaking PCM outside the cooling system 100. Advantageously, by filtering the PCM at the expansion chamber 142 and by having an easily removable expansion chamber 142, the PCM can be routinely cleaned of solid impurities that may be generated and/or collected during the thermal cycling process by removing and replacing and/or cleaning the expansion chamber 142.

In some embodiments, the cooling system 100 can further include one or more pumps 150 in line with any of the conduits of the system as driving elements to move or otherwise advance the PCM through the cooling system 100. In some embodiments, the pump 150 can be positioned to be in line with the second conduit 140. The pump 150 can assist in pumping the liquid PCM exiting the heatsink 130 back to the heat exchanger 160. In some embodiments, the pumps 150 can be arranged to be in series or in parallel with respect to the conduits to/from the heatsink 130. Pumps 150 which are in parallel could be utilized to offer redundancy in the system. In some embodiments, the pump 150 can be a diaphragm pump, a lobe pump, a vane pump, an internal gear pump or an oil transfer gear pump. Ideally, the pump 150 can be in the form of a hydraulic gear pumps or an external gear pump.

In some embodiments, the pump 150 can be controlled by a controller 200 to pump the PCM in the second conduit 140 back to the heat exchanger 160 at a pressure of 20 to 50 PSI. Advantageously, a pump 150 positioned on the second conduit 140 can apply sufficient pressure within the cooling system 100 such that it assists in moving the semi-solid PCM in the first conduit 110. In some embodiments where the cooling system 100 includes an expansion chamber 142 on the second conduit 140, the pump 150 would ideally be positioned after the expansion chamber 142 on the second conduit 140.

In some embodiments, the pump 150 can be controlled by the controller 200 to vary its operation. The controller 200 can measure the pressure within the cooling system 100 at various points, and adjust the speed of the pump 150 as desired or required to prevent applying too high a pressure to the first conduit 110, second conduit 140, or other components of the cooling system 100. The controller 200 can regulate the speed of the pump 150 in tandem with any other driving elements utilized by the cooling system 100. In some embodiments, a maximum system pressure can be set to prevent or substantially prevent damage to the various components of the cooling system 100.

In some embodiments of a cooling system 100, such as embodiments utilizing a pump 150 as a driving element, the cooling system 100 can further include a third conduit 144 (e.g. a bypass conduit, a conduit bypass, a bypass) to prevent or substantially prevent damage to the cooling system 100 in case of an over-pressurization of components due to improper operation of a pump 150. The third conduit 144 can be connected to the second conduit 140 by valving 146, such as a three way valve, that can divert fluid flow to either the second conduit 140 or to the third conduit 144. The third conduit 144 can be positioned between the heatsink 130 and an expansion chamber 142 or pump 150 along the second conduit 140 to direct flow around those components in the event of use. The controller 200 can issue commands to the valving 146 such that, if pressure within the system exceeds a threshold pressure value, then the valving 146 can actuate and direct flow of the PCM around the expansion chamber 142 and/or the pump 150. By directing fluid flow around the expansion chamber 142 and/or pump 150, pressure added to the cooling system 100 by the pump 150 can be reduced and/or eliminated. The valving 146 can be connected to the controller 200 such that the controller 200 can issue commands whether fluid flow is diverted from the second conduit 140 to the third conduit 144 or toward the expansion chamber 142 and/or pump 150. The third conduit 144 can rejoin the second conduit 140 after the pump 150, can independently lead to the heat exchanger 160, and/or can lead to an emergency drain or pressure relief 145 to allow PCM to exit the cooling system 100. Flow to a pressure relief 145 can be regulated by a valve, by positioning of the pressure relief 145 above a head pressure of the driving elements within the cooling system 100, and/or by various other means. Once pressure of the system drops to below the threshold pressure value, the valving 146 can direct the PCM to flow toward the expansion chamber 142 and/or the pump 150.

In some embodiments, the pump 150 can include a heating element 152 configured to heat the PCM within the pump 150 in the event that a portion of the PCM within the pump 150 has solidified. This can occur if the cooling system 100 is starting from a cold state or if the heat source 120 is not providing sufficient thermal energy to liquefy the semi-solid PCM from the first conduit 110. In some embodiments, the heating element 152 can be a cartridge heater, a band heater fitted around the second conduit 140 or pump 150, strip heaters, and/or any other suitable heating elements as desired or required. In some embodiments, the heating element 152 can be positioned around the second conduit 140 such that it can liquefy PCM that has solidified within the second conduit 140, which can occur if the system is starting from a cold state. In some embodiments, the heating element 152 can be positioned to warm the heat exchanger 160 such that it can warm PCM within the heat exchanger 160 to promote flow of PCM through the cooling system 100.

In some embodiments, the pump 150 can further include a heating system to provide warm fluid to the outer surface of the pump 150. The heating system can warm the exterior surface of the pump 150, and thus the PCM within the pump 150. The heating system can warm the pump 150 and the PCM within the pump 150 if the PCM in the pump 150 had solidified.

The heating element 152 can be configured to receive commands from the controller 200. The controller 200 can issue commands to the heating element 152 to heat the pump 150 and/or the second conduit 140 leading to the pump 150 if certain conditions are met. If a sensor 202 connected to the pump 150 indicates that the PCM within the pump 150 is below a certain temperature, such as a solidification temperature for a PCM within the cooling system 100, then the controller 200 can issue commands to the heating element 152 to heat the contents of the pump 150 such that the pump 150 can pump fluid PCM through the cooling system 100. In some embodiments, if a temperature sensor positioned anywhere on the cooling system 100 detects that the PCM is below a solidification temperature, the controller 200 can issue commands to the heating element 152 to heat any component of the cooling system 100.

The cooling system 100 can further include a heat exchanger system 160 (e.g., solidifier, heat exchanger, etc.) which receives liquid PCM from the second conduit 140. The heat exchanger 160 can include a housing 162 to hold the liquid PCM from the second conduit 140 to be cooled and transmitted out the first conduit 110. PCM can flow through the housing 162 within an internal chamber 168 that contains an auger 166 (e.g., heat exchanger auger). The auger 166 can contact the PCM and rotate within the internal chamber 168 (e.g., an interior chamber of the heat exchanger, PCM chamber, solidifier chamber, etc.) to push or otherwise advance the PCM through the heat exchanger 160. Advantageously, use of an auger 166 within the system can remove PCM that has solidified on the interior wall of the internal chamber 168, allowing for more liquid PCM to contact the interior wall of the internal chamber 168 and be cooled to the solidification point. In some embodiments, the motor 180 can spin the auger 166 at a rate of 200 revolutions per minute. The speed at which the motor 180 rotates can be modified based on the desired outgoing temperature for the semi-solid PCM, the material properties of the PCM, and/or any other factors as desired or required.

The housing 162 can be filled with cooling fluid or medium from a secondary cooling element 170 to cool the contents of the internal chamber 168. The internal chamber 168 can have its internal surface in fluid communication with the PCM and its external surface in fluid communication with the cooling medium from the secondary cooling element 170. The cooling medium in the housing 162 can, in some embodiments, not be in fluid communication with the internal chamber 168. The internal chamber 168 can include a plurality of surface features such as ridges, channels, pathways, or other features increasing the surface area of the internal chamber 168. The surface features on the internal chamber 168 can increase the contact area for the cooling medium from the secondary cooling element 170 to cool the PCM within the internal chamber 168.

In some embodiments, the cooling medium in the housing 162 can be added and removed from the housing 162 by one or more cooling system connections 164 that connect the housing 162 to a secondary cooling element 170. The secondary cooling element 170 can be filled with different fluids as desired or required, including but not limited to distilled or demineralized water, chemically pure water, refrigerants, polyglycol mixtures, and/or any other refrigeration medium.

Rotation of the auger 166 within the internal chamber 168 can be performed by a motor 180 operatively connected to the heat exchanger 160. The motor 180 can be controlled by a controller 200 which drives the rotation speed of the auger 166. The controller 200 can specify the rotation rate of the auger 166 such that the semi-solid PCM exiting the heat exchanger 160 is at an adequate temperature and/or the PCM is an appropriate mixture of solid and liquid to provide sufficient cooling for the surface 120. In some embodiments, the heat exchanger 160 can include a pump substantially similar to a pump 150 instead of and/or in addition to a motor 180. In some embodiments, the motor 180 can be designed such that its operation can power rotation of the auger 166 as well as any pump 150 arranged within the cooling system 100.

Operation of the auger 166 can be controlled by the controller 200 based on readings from one or more temperature probes 202 positioned throughout the cooling system 100, such as on the first conduit 110, heatsink 130, pump 150, and/or internal chamber 168. Once the controller 200 determines that the PCM within the heat exchanger 160 has been sufficiently cooled, it can control various components within the cooling system 100, such as the auger 166, to transmit the now semi-solid PCM from the heat exchanger 160 to the first conduit 110, completing a cycle. In some embodiments, the sufficient cooling could be determined by a sensor 202 positioned along the first conduit 110 and/or the internal chamber 168.

The internal chamber 168 can be cooled by operation of the secondary cooling element 170. The secondary cooling element 170 can be filled with water, refrigerant, or any other appropriate cooling medium to remove thermal energy from the PCM within the cooling system 100. Advantageously, use of the refrigerants or other cooling mediums within the secondary cooling element 170 rather than to cool the heat source 120 can contain possible leaks of the cooling medium to be isolated from the heat source 120. In some embodiments, the secondary cooling element 170 can provide a cooled medium at a temperature of approximately 70 degrees Fahrenheit, and can remove the heated medium at a temperature of approximately 80 degrees Fahrenheit at a rate of approximately 1 Liter per minute.

In some embodiments, the cooling system 100 can be fluidically sealed such that PCM does not enter or exit the cooling system 100. In some embodiments, the cooling system 100 can be fluidically sealed such that PCM does not enter or exit the cooling system 100 except where designed, such as where the cooling system 100 includes a third conduit 144 with an emergency pressure relief 145.

In some embodiments, the cooling system 100 can be filled with one or more different phase change materials as desired or required.

In some embodiments, the cooling system 100 can be filled with one phase change material. PCM in general can be advantageous in comparison to conventional coolant mediums such as refrigerants as PCMs can be non-toxic, solid or semi-solid at room temperature, inexpensive, and readily available. In comparison to refrigerants, PCM contains no polyfluoroalkyl substances (or, “PFAS”). A PCM used in the cooling system 100 can be non electrically conductive such that, in the event of a leak onto electrical components, damage to the electrical components cooled by the cooling system 100 can be limited. Advantageously, due to the utilization of thermal energy absorption associated with latent heat as well as sensible heat, the cooling system 100 can require substantially less PCM to adequately cool the heat source 120 compared to a conventional system.

In some embodiments, the PCM used within a system is a petroleum jelly product. In some embodiments, the PCM can be formulated to melt at 98° F. The PCM can have a phase change enthalpy of 95 Joules per gram (J/g) in an unmodified state. Additives to the PCM can modify the PCMs characteristics. For example, a petroleum jelly modified by hydrated salt can have a phase change enthalpy of 80 J/g. A PCM can have a fusion temperature of 125° F. As a result of various additives, the fusion temperature can be changed to be lower to allow the PCM to absorb energy in the form of latent heat due to solidification and melting. In some embodiments, additives to the PCM can include Calcium Chloride or Sodium Sulfate.

In some embodiments, the cooling system 100 can take advantage of the higher thermal capacity of PCMs compared to conventional cooling mediums to increase its efficiency. Water can typically have a thermal capacity of 200 Watts per square centimeter (W/cm²) of surface area contact with the heatsink 130. Typical refrigerants used in cooling systems can have a thermal capacity of 400 W/cm². In some embodiments, PCM with several modifiers can have a thermal capacity of 400 W/cm², which can be higher than conventional refrigerants.

In some embodiments, the PCM can be a semi-solid mix of hydrocarbons such as, for example, a soft paraffin or petroleum jelly configured to melt at approximately 99° F. In some embodiments, the liquid PCM can enter the heat exchanger 160 in a temperature range between 104° F. and 120° F. In some embodiments, the semi-solid PCM can exit the heat exchanger 160 and be directed by the auger 166 in a temperature range between 7° and 90° F. The flow rate of the cooling medium of the secondary cooling element 170 can be adjusted as desired or required to effectuate sufficient latent or sensible heat transfer from the PCM within the heat exchanger 160.

In some embodiments, a PCM mixture can utilize a base of a petroleum jelly or soft paraffin and can include additives of hydrated salts to form a hydrated salt/paraffin composite (HPC). As used herein, a PCM can refer to the use of a HPC and/or of any other phase changing material for use within a cooling system 100 or similar system. The HPC can have a heat capacity substantially more beneficial for use in the cooling system 100 compared to a standard cooling medium. The HPC can have an enthalpy of approximately 200 J/g. Advantageously, this additional heat capacity can aid in reducing the volume of cooling medium required to move a given amount of heat from the chipsets. Advantageously, the hydrated salts in the HPC can stay in suspension within the petroleum jelly or soft paraffin to reduce potential corrosion to system materials. The ratio between the petroleum jelly and the hydrated salts can be adjusted to modify physical characteristics of the HPC as desired or required for particular use cases. In some embodiments, the HPC can consist of a 2:1 ratio of hydrated salt to petroleum jelly. In some embodiments, the HPC can have a ratio of hydrated salt to petroleum jelly from a range of 1:3 to 3:1.

In some embodiments, the cooling system 100 can include a plurality of heatsinks 130 to provide cooling to a plurality of cooled surfaces 120. Conduits 110 can lead from the heat exchanger 160 to each of the heatsinks 130. Each heatsink 130 can have a second conduit 140 to remove heated PCM from the heatsink 130. The second conduits 140 can lead to a collection channel or can each be fitted with a pump 150. The second conduits 140 can be fitted with other components as previously described, including but not limited to an expansion chamber 142, third conduit 144 and valving 146, a pump 150, or any other components.

Advantageously, flow of the PCM to different cooled surfaces 120 can be self-regulating. In systems including multiple heatsinks 130, if one of the cooled surfaces 120 is not generating sufficient heat to liquefy the PCM, then flow to that surface 120 can naturally be reduced due to the higher viscosity of the PCM when solidified. Once the surface 120 generates sufficient heat, the PCM within the heatsink 130 heats up, and flow can resume to the heatsink 130. In some embodiments, the distribution of the flow within the cool conduits 110 can be regulated through the use of a flow distribution valve, which can be controlled by a controller 200 as disclosed herein.

In some embodiments, the cooling system 100 can be configured for use within a computer server, cabinet, or rack system to provide cooling to one or more electrical components within the electronic cabinet. The cooling system 100 can be positioned such that the heat exchanger 160 is mounted above the electrical components to which it provides semi-solid PCM by one or more cool conduits 110. The secondary cooling element 170 can be arranged adjacent the heat exchanger 160. Alternatively, the secondary cooling element 170 can be positioned elsewhere within the facility housing the electronic cabinet, and the heat exchanger 160 can receive the cooling medium via connections 164. The cooling system 100 can receive the cooling medium from the secondary cooling element 170 supplied by the facility housing the electronic cabinet. Ideally, the heat exchanger 160 can be positioned such that the semi-solid PCM flows with the flow of gravity to the cooled surfaces 120, and the liquid PCM flows against the flow of gravity to the heat exchanger 160.

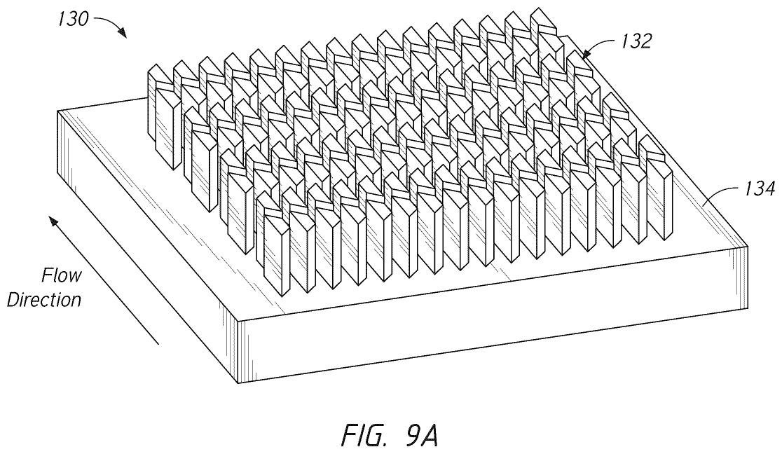

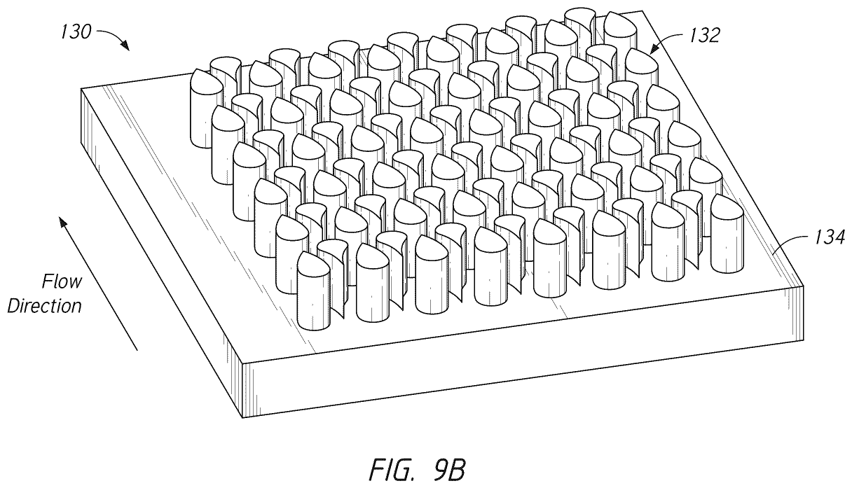

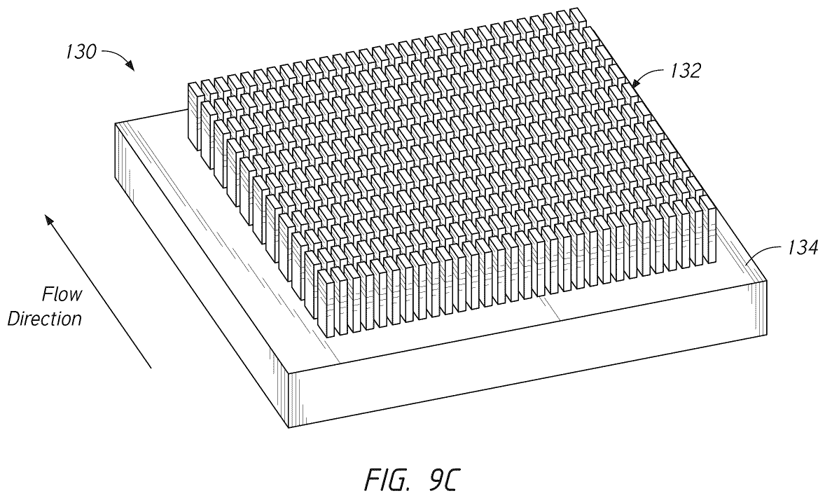

FIGS. 9A through 9C depict potential embodiments for configurations of a heatsink 130 for use with the PCM from the cooling system 100. The heatsink base 134 can directly contact the heat source 120. In some embodiments, thermal paste or similar thermal transfer mediums can be positioned between the heatsink base 134 and the heat source 120 to facilitate thermal transfer. The heatsink base 134 can support a plurality of fins 132 to remove thermal energy from the heat source 120. Semi-solid PCM can be provided by the first conduit 110 at a temperature and phase of matter suitable to remove thermal energy from the heat source 120. The PCM in the heatsink 130 can be at a temperature adequate to remove thermal energy from the system. The PCM entering the heatsink 130 can be at approximately 88° F. and be in a semi-solid state. The PCM exiting the heatsink 130 can be at approximately 126° F. and be in a mostly liquid state. The PCM exiting the heatsink 130 can potentially include some solid segments of PCM.

The heatsinks 130 depicted in FIGS. 9A through 9C represent various depictions of potential fin configurations suitable for removing thermal energy from the heat source 120. In some embodiments, the heatsink base 134 can include a plurality of fins 132 that increase the surface area of the heatsink 130 exposed to the PCM. The fins 132 can define a flow path designed to assist the distribution of thermal energy from the heat source 120 to the PCM.

The PCM flowing through the fins 132 can enter the heatsink 130 at a semi-solid, chilled state, and can leave the heatsink 130 at a liquid, heated state. The PCM flowing through the fins 132 can be heated by the heat source 120 such that at least a portion of the semi-solid PCM is liquefied as it absorbs thermal energy from the heat source 120. The fins 132 can be arranged on the heatsink base 134 in rows aligned to define flow paths for the PCM to flow through the heatsink.

FIG. 9A depicts one potential embodiment of a heatsink 130 with fins 132 arranged on the heatsink base 134 such that the fins 132 can facilitate thermal transfer to the PCM from the heatsink 130. The fins 132 can be configured with sharp edges on their leading edge which can assist in cutting up semi-solid or solid portions of the PCM flowing through the heatsink 130. The fins 132 can include dull edges on their trailing edge which can assist in diverting flow of the PCM into the next row of fins 132 downstream. Advantageously, by cutting up larger semi-solid or solid PCM chunks into smaller PCM chunks to increase their surface area, thus increasing the amount of thermal transfer from fins 132 to the semi-solid or solid PCM. The fins 132 can be configured to have various gaps between the fins 132 such that PCM can flow through the channels and contact sharp edges to further cut, slice, fracture, and/or otherwise separate semi-solid or solid PCM segments, pieces, portions, masses, or otherwise semi-solid or solid PCM flowing through the heatsink 130. The fins 132 can promote uniform suspension, emulsion, and/or suspension of solids within the liquid PCM. In some embodiments, the fins 132 can be arranged such that the flow path of the PCM can be directed into the leading edge of the fins 132 further along the flow direction. As shown in FIG. 9A, the fins 132 can be vaguely trapezoid shaped. In some embodiments, the fins 132 can be arranged on the heatsink base 134 such that PCM passing between one row of fins 132 is directed to the leading edge of the next row of fins 132, to further increase the potential to fracture and/or divide larger PCM segments flowing through the heatsink 130.

FIG. 9B depicts another potential embodiment of a heatsink 130 with fins 132 configured to transmit thermal energy from the heat source 120 to the PCM flowing through the heatsink 130. The fins 132 can be shaped with a teardrop shape extending out from the heatsink base 134. Alternate shapes similar to teardrops having more defined and/or sharpened leading edges can also be arranged on the same heatsink base 134 such that a heatsink 130 has alternating rows of dull leading edge teardrop shaped fins 132 and rows of sharpened leading edge teardrop-like shaped fins 132. The dulled leading edge of the fins 132 can help direct PCM flow around the first row of fins 132 into the sharpened leading edge of the next row of fins 132. These sharper leading edges can cut, slice, and/or fracture semi-solid or solid PCM segments flowing through the heatsink 130 to increase surface area of the PCM, and thus increase thermal transfer between the fins 132 and the PCM. The fins 132 can be configured to have various gaps between the fins 132 such that PCM can flow through the channels and impact the sharpened leading edges to further cut, slice, and/or fracture semi-solid or solid PCM segments flowing through the heatsink 130.

FIG. 9C depicts another potential embodiment of a heatsink 130 with fins 132 configured to transmit thermal energy from the heat source 120 to the PCM flowing through the heatsink 130. The fins 132 can be configured to have various gaps between the fins 132 such that PCM can flow through the channels and contact sharp edges to further cut, slice, and/or fracture semi-solid or solid PCM segments flowing through the heatsink 130. The fins 132 can be vaguely rectangular shaped.

The exact sizes and dimensions of the fins 132 arranged on the heatsink 130 can vary as desired or required. In some embodiments, the fins 132 can include a variety of shapes and/or sizes on a single heatsink base 134. For example, the fins 132 on a heatsink base 134 could include rectangularly shaped fins, teardrop shaped fins, trapezoid shaped fins, and/or any other shape fin as desired or required. The fins 132 can be arranged in rows such that along an axis, a repeated pattern of fins 132 are presented on the heatsink base 134. The axial pattern of fins 132 can be repeated along another axis of the heatsink base 134 to create an array of fins, such as the examples depicted in FIGS. 9A-9C.

In some embodiments, the cooling system 100 can include a controller 200 configured to control operation of one or more of the components of the cooling system 100. The controller 200 can issue commands to an auger 112, a bypass valving 146, a pump 150, a heating element 152, a secondary cooling element 170, a motor 180, and/or any other components of the cooling system 100.

The controller 200 can further include sensors 202 positioned on one or more of the following: the first conduit 110, the auger 112, the heat source 120, the heatsink 130, the second conduit 140, the valving 146, the expansion chamber 142, the pump 150, the heating element 152, the internal chamber 168, the secondary cooling element 170, the motor 180, and/or any other components of the cooling system 100. The probes 202 can read one or more qualities of the cooling system 100, such as the pressure and/or temperature of various components of the cooling system 100, the speed of rotation of the auger 112, pump 150, and/or motor 180, the electrical current drawn by the auger 112, pump 150, and/or motor 180, and various other components of the cooling system 100.

The controller 200 can also calculate data relevant to the operation of the cooling system 100. For example, an increase in the electrical current drawn by the auger 112, pump 150, and/or motor 180 can be an indication of solidification of the PCM at various components of the cooling system 100. The controller 200 can use this information to issue various commands to the cooling system 100, such as actuating the valving 146 to direct fluid flow around the pump 150, instructing the heating element 152 to heat the PCM within the second conduit 140 and/or the pump 150, modifying rotation speed of the either auger 112, 166, modifying flow rate of the cooling medium within the secondary cooling element 170, and/or the like.

While certain embodiments of the inventions have been described, these embodiments have been presented by way of example only and are not intended to limit the scope of the disclosure. Indeed, the novel methods and systems described herein may be embodied in a variety of other forms. Furthermore, various omissions, substitutions and changes in the systems and methods described herein may be made without departing from the spirit of the disclosure. The accompanying claims and their equivalents are intended to cover such forms or modifications as would fall within the scope and spirit of the disclosure. Accordingly, the scope of the present inventions is defined only by reference to the appended claims.

Features, materials, characteristics, or groups described in conjunction with a particular aspect, embodiment, or example are to be understood to be applicable to any other aspect, embodiment or example described in this section or elsewhere in this specification unless incompatible therewith. All of the features disclosed in this specification (including any accompanying claims, abstract and drawings), and/or all of the steps of any method or process so disclosed, may be combined in any combination, except combinations where at least some of such features and/or steps are mutually exclusive. The protection is not restricted to the details of any foregoing embodiments. The protection extends to any novel one, or any novel combination, of the features disclosed in this specification (including any accompanying claims, abstract and drawings), or to any novel one, or any novel combination, of the steps of any method or process so disclosed.

Furthermore, certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a claimed combination can, in some cases, be excised from the combination, and the combination may be claimed as a subcombination or variation of a subcombination.

Moreover, while operations may be depicted in the drawings or described in the specification in a particular order, such operations need not be performed in the particular order shown or in sequential order, or that all operations be performed, to achieve desirable results. Other operations that are not depicted or described can be incorporated in the example methods and processes. For example, one or more additional operations can be performed before, after, simultaneously, or between any of the described operations. Further, the operations may be rearranged or reordered in other implementations. Those skilled in the art will appreciate that in some embodiments, the actual steps taken in the processes illustrated and/or disclosed may differ from those shown in the figures. Depending on the embodiment, certain of the steps described above may be removed, others may be added. Furthermore, the features and attributes of the specific embodiments disclosed above may be combined in different ways to form additional embodiments, all of which fall within the scope of the present disclosure. Also, the separation of various system components in the implementations described above should not be understood as requiring such separation in all implementations, and it should be understood that the described components and systems can generally be integrated together in a single product or packaged into multiple products.

For purposes of this disclosure, certain aspects, advantages, and novel features are described herein. Not necessarily all such advantages may be achieved in accordance with any particular embodiment. Thus, for example, those skilled in the art will recognize that the disclosure may be embodied or carried out in a manner that achieves one advantage or a group of advantages as taught herein without necessarily achieving other advantages as may be taught or suggested herein.

Conditional language, such as “can,” “could,” “might,” or “may,” unless specifically stated otherwise, or otherwise understood within the context as used, is generally intended to convey that certain embodiments include, while other embodiments do not include, certain features, elements, and/or steps. Thus, such conditional language is not generally intended to imply that features, elements, and/or steps are in any way required for one or more embodiments or that one or more embodiments necessarily include logic for deciding, with or without user input or prompting, whether these features, elements, and/or steps are included or are to be performed in any particular embodiment.

Conjunctive language such as the phrase “at least one of X, Y, and Z,” unless specifically stated otherwise, is otherwise understood with the context as used in general to convey that an item, term, etc. may be either X, Y, or Z. Thus, such conjunctive language is not generally intended to imply that certain embodiments require the presence of at least one of X, at least one of Y, and at least one of Z.

Language of degree used herein, such as the terms “approximately,” “about,” “generally,” and “substantially” as used herein represent a value, amount, or characteristic close to the stated value, amount, or characteristic that still performs a desired function or achieves a desired result. For example, the terms “approximately”, “about”, “generally,” and “substantially” may refer to an amount that is within less than 10% of the stated amount. As another example, in certain embodiments, the terms “generally parallel” and “substantially parallel” refer to a value, amount, or characteristic that departs from exactly parallel by less than or equal to 15 degrees, 10 degrees, 5 degrees, 3 degrees, 1 degree, or 0.1 degree. The ranges disclosed herein also encompass any and all overlap, sub-ranges, and combinations thereof, and any specific values within those ranges. Language such as “up to,” “at least,” “greater than,” “less than,” “between,” and the like includes the number recited. Numbers and values used herein preceded by a term such as “about” or “approximately” include the recited numbers. For example, “approximately 7 mm” includes “7 mm” and numbers and ranges preceded by a term such as “about” or “approximately” should be interpreted as disclosing numbers and ranges with or without such a term in front of the number or value such that this application supports claiming the numbers, values and ranges disclosed in the specification and/or claims with or without the term such as “about” or “approximately” before such numbers, values or ranges such, for example, that “approximately two times to approximately five times” also includes the disclosure of the range of “two times to five times.”

The scope of the present disclosure is not intended to be limited by the specific disclosures of preferred embodiments in this section or elsewhere in this specification and may be defined by claims as presented in this section or elsewhere in this specification or as presented in the future. The language of the claims is to be interpreted broadly based on the language employed in the claims and not limited to the examples described in the present specification or during the prosecution of the application, which examples are to be construed as non-exclusive.

We claim:

1. A cooling system comprising:
a conduit having at least a portion thereof in thermal communication with a heat emitting object;
a heat exchanger in communication with the conduit, the heat exchanger comprising a housing comprising an internal chamber;
a phase change material;
a driving element adapted to advance the phase change material through the internal chamber and the conduit during operation of the cooling system; and
a secondary cooling element in thermal communication with the heat exchanger, the secondary cooling element adapted to remove heat from the phase change material as the phase change material is advanced through the internal chamber of the heat exchanger;
wherein:
the cooling system is adapted to remove heat from the heat emitting object as the phase change material advances through at least the portion of the conduit that is in thermal communication with the heat emitting object so that at least a portion of the phase change material changes from a solid phase or a semi-solid phase to a liquid phase from the heat removed from the heat emitting object; and
at least a portion of the phase change material cools and transitions from the liquid phase to the solid phase or the semi-solid phase as the phase change material passes through the internal chamber and heat is removed from the phase change material by the secondary cooling element.

2. The cooling system of claim 1, wherein the phase change material exiting the heat exchanger comprises a mixture of a solid and/or a semi-solid material and a liquid material.

3. The cooling system of claim 1, wherein the phase change material comprises a soft paraffin.

4. The cooling system of any of claim 1, wherein the driving element comprises an auger within the internal chamber.

5. The cooling system of claim 4, wherein:
a rotational speed of the auger is controlled by a controller;
the controller reduces the rotational speed of the auger if a temperature sensor in communication with the phase change material in the conduit detects that a temperature of the phase change material exiting the heat exchanger is above a first temperature; and
the controller increases the rotational speed of the auger if the temperature sensor detects that a temperature of the phase change material exiting the heat exchanger is below the first temperature.

6. The cooling system of claim 1, wherein:
the secondary cooling element provides a cooling medium to the housing and/or the heat exchanger; and
the cooling medium cools the internal chamber such that at least a portion of the phase change material transitions from the liquid phase to the solid phase or the semi-solid phase.

7. The cooling system of claim 1, wherein the driving element comprises a pump adapted to move the phase change material through the conduit.

8. The cooling system of claim 1 further comprising a heating element, wherein, if a temperature sensor in thermal communication with the phase change material is below a solidification temperature, the heating element heats the cooling system.

9. The cooling system of claim 7, wherein:
the conduit further comprises a bypass conduit;
wherein the bypass conduit diverts from the conduit around the pump so as to bypass the pump; and
a valve controls a flow of the phase change material through the bypass conduit.

10. The cooling system of claim 9, further comprising a controller, wherein:
if a pressure sensor detects that a pressure within the cooling system exceeds a threshold pressure value, the controller issues commands to the valve to divert a flow of the phase change material to bypass the pump, and
when pressure within the cooling system returns to below the threshold pressure value, the controller actuates the valve to allow the flow of the phase change material to advance to the pump.

11. The cooling system of claim 1, further comprising a heatsink in thermal communication with the heat emitting object and the portion of the conduit in thermal communication with the heat emitting object.

12. The cooling system of claim 11, wherein the heatsink comprises a plurality of fins adapted to facilitate thermal communication between the phase change material and the heat emitting object.

13. The cooling system of claim 12, wherein each of the plurality of fins comprises a sharp leading edge adapted to separate large solid phase change material segments or semi-solid phase change material segments into smaller solid phase change material segments or semi-solid phase change material segments.

14. The cooling system of claim 1, further comprising an expansion chamber in communication with the conduit, the expansion chamber adapted to accommodate expansion and contraction of the phase change material due to changes of phase.

15. The cooling system of claim 1, wherein the heat emitting object comprises a chipset or an electronic component.

16. The cooling system of claim 1, wherein the phase change material does not comprise solid material at room temperature.

17. A cooling system comprising:
a conduit having at least a portion thereof in thermal communication with a heat emitting object;
a heat exchanger in communication with the conduit, the heat exchanger comprising a housing comprising an internal chamber;
a phase change material;
an auger within the internal chamber, the auger adapted to move the phase change material through the internal chamber during operation of the cooling system;
a secondary cooling subsystem in thermal communication with the heat exchanger, the secondary cooling subsystem adapted to remove heat from the phase change material as the phase change material is advanced through the internal chamber of the heat exchanger; and
a pump configured to move the phase change material through the conduit;
wherein:
the cooling system is in thermal communication with a heat emitting object to remove heat from the heat emitting object so that at least a portion of the phase change material changes from a solid phase or semi-solid phase to a liquid phase; and
as the phase change material passes through the internal chamber during operation of the cooling system, at least a portion of the phase change material cools and transitions from the liquid phase to the solid phase or semi-solid phase.

18. The cooling system of claim 17, further comprising a controller adapted to control operation of at least the auger and the pump and a plurality of sensors adapted to provide data to the controller.

19. A method of cooling a heat emitting object, the method comprising:
removing heat from the heat emitting object by moving a phase change material through a portion of a conduit that is in thermal communication with the heat emitting object so that the phase change material absorbs heat from the heat emitting object, thereby cooling the heat emitting object,
wherein, when the phase change material absorbs heat from the heat emitting object, at least a portion of the phase change material changes from a solid state or a semi-solid state to a liquid state;
moving the phase change material away from the heat emitting object and through an internal chamber of a heat exchanger;
cooling the phase change material in the heat exchanger to convert at least some of the phase change material from the liquid state to the semi-solid state or the solid state; and
transporting the phase change material away from the heat exchanger using a driving element such that the phase change material moves back to the portion of the conduit that is in thermal communication with the heat emitting object.

20. The method of claim 19, wherein the phase change material exiting the heat exchanger comprises a mixture of a semi-solid material and/or a solid material and a liquid material, with the mixture comprising predominantly the semi-solid material and/or the solid material.

21. The method of claim 19, wherein the driving element comprises an auger within the internal chamber.

22. The method of claim 21, further comprising controlling a rotational speed of the auger, comprising:
reducing the rotational speed of the auger if a temperature of the phase change material exiting the heat exchanger is above a first temperature; and
increasing the rotational speed of the auger if the temperature of the phase change material exiting the heat exchanger is below the first temperature.

23. The method of claim 19, wherein the driving element comprises a pump adapted to move the phase change material through the conduit.

24. The method of claim 19, wherein cooling the heat emitting object comprises advancing the phase change material through a heatsink in thermal communication with the conduit and the heat emitting object, the heatsink being in fluid communication with the conduit.

25. The method of claim 24, wherein the heatsink comprises a plurality of fins adapted to facilitate thermal communication between the phase change material and the heat emitting object.

26. The method of claim 19, further comprising an expansion chamber arranged on the conduit, the expansion chamber adapted to accommodate expansion and contraction of the phase change material due to changes of phase.
